(19) United States
(12) Patent Application Publication
(10) Pub. No.: US 2026/0192558 A1
(43) Pub. Date: Jul. 9, 2026

(54) APPARATUS FOR MANUFACTURING COATED GLASS AND ELECTRONIC DEVICE

(71) Applicant: Samsung Display Co., LTD., Yongin-si (KR)

(72) Inventor: Kyung Man KIM, Yongin-si (KR)

(21) Appl. No.: 19/385,523

(22) Filed: Nov. 11, 2025

(30) Foreign Application Priority Data
Jan. 7, 2025 (KR) 10-2025-0002297

(51) Int. Cl. B32B 37/15; B32B 3/04; B32B 3/18; B32B 7/12; B32B 17/10; B32B 27/18; B32B 37/00; B32B 38/00; B32B 38/10; H05K 5/03

(52) U.S. Cl. CPC B32B 37/15; B32B 3/04; B32B 3/18; B32B 7/12; B32B 17/10; B32B 27/18; B32B 37/0046; B32B 38/10; H05K 5/03; B32B 2038/0076; B32B 2305/72; B32B 2307/422; B32B 2457/20

(57) ABSTRACT

An apparatus for manufacturing coated glass includes a substrate supply unit wound with a substrate with a first film attached to a first side of glasses and a protective film attached to a second side of the glasses, a first film removing unit which removes the protective film of the substrate, a resin supply unit which supplies a resin on the first film and the glasses, a first roller which conveys the first film, and a second roller spaced apart from the first roller and which conveys a second film, where the first film and the second film are in close contact between the first roller and the second roller, and the resin is filled around the glasses.

This application claims priority to Korean Patent Application No. 10-2025-0002297 filed on Jan. 7, 2025, and all the benefits accruing therefrom under 35 U.S.C. § 119, the content of which in its entirety is herein incorporated by reference.

### BACKGROUND

### 1. Field

The disclosure relates to an apparatus for manufacturing coated glass and an electronic device including the coated glass.

### 2. Description of the Related Art

As interest in information display has been increased, research and development on a display device is continuously being conducted.

### SUMMARY

Embodiments of the invention provide an apparatus for manufacturing coated glass, which is manufactured with improved quality and reduced production cost.

According to an embodiment of the disclosure, an apparatus for manufacturing coated glass includes: a substrate supply unit on which a substrate is wound, where the substrate includes glasses, a first film attached to a first side of the glasses and a protective film attached to a second side of the glasses; a first film removing unit which removes the protective film of the substrate; a resin supply unit which supplies a resin on the first film and the glasses; a first roller which conveys the first film; and a second roller spaced apart from the first roller and which conveys a second film, where the first film and the second film are in close contact between the first roller and the second roller, and the resin is filled around the glasses between the first film and the second film.

In an embodiment, the second film may pull up the resin from the resin supply unit and provide the resin on the first film and the glasses.

In an embodiment, the resin supply unit may coat the resin on the second film.

In an embodiment, the resin supply unit may coat the resin on the first film and the glasses.

In an embodiment, a thickness of the coated glass may be equal to a gap between the first roller and the second roller.

In an embodiment, the apparatus for manufacturing coated glass may further include a curing unit which cures the resin filled around the glasses between the first film and the second film.

In an embodiment, the curing unit may include a first plate which presses the first film and a second plate which presses the second film.

In an embodiment, the apparatus for manufacturing coated glass may further include a winding roller on which the coated glass is wound.

In an embodiment, the apparatus for manufacturing coated glass may further include a second film which removes unit removing the second film.

In an embodiment, the apparatus for manufacturing coated glass may further include an attachment unit which attaches a release film on the resin.

In an embodiment, the attachment unit may include a third roller and a fourth roller, which are spaced apart from each other.

According to an embodiment of the disclosure, an electronic device includes: a display panel; and a coated glass on the display panel, wherein the coated glass is manufactured by the apparatus for manufacturing coated glass.

In an embodiment, the coated glass may include glass on the display panel and a resin between the display panel and the glass.

In an embodiment, the coated glass may further include a first adhesive layer between the display panel and the resin.

In an embodiment, the electronic device may further include a protective layer on the coated glass.

In an embodiment, the coated glass may further include a second adhesive layer between the glass and the protective layer.

In an embodiment, the coated glass may further include a light shielding layer between the glass and the protective layer.

In an embodiment, the light shielding layer may overlap an edge of the glass.

In an embodiment, the resin may include an ultraviolet (UV) absorber.

In an embodiment, the resin may include a fluorescent additive.

Further details of other embodiments are contained in the description and the drawings.

According to embodiments of the disclosure, the resin is coated on the glass by using the roll-to-roll gap coating, so that the thickness and shape of the resin can be easily controlled, thereby improving the flatness of the resin and reducing the manufacturing cost.

Effects according to embodiments are not limited by the content illustrated above, and more various effects are included in the specification.

### BRIEF DESCRIPTION OF THE DRAWINGS

FIG. 1 is a schematic view of an apparatus for manufacturing coated glass according to an embodiment.

FIG. 2 is an enlarged schematic view of an apparatus for manufacturing coated glass according to an embodiment.

FIGS. 3 to 7 are schematic views of an apparatus for manufacturing coated glass according to an embodiment.

FIGS. 8 to 13 are cross-sectional views of a coated glass according to an embodiment.

FIG. 14 is a schematic view of an apparatus for manufacturing coated glass according to an embodiment.

FIG. 15 is a cross-sectional view of a coated glass according to an embodiment.

FIG. 16 is a schematic view of an apparatus for manufacturing coated glass according to an embodiment.

FIG. 17 is a top view of a coated glass according to an embodiment.

FIG. 18 is a cross-sectional view of a coated glass according to an embodiment.

FIG. 19 is a cross-sectional view of a display device according to an embodiment.

FIG. 20 is a plan view of the display panel according to the embodiment of FIG. 19.

FIG. 21 is a block diagram of an electronic device according to an embodiment.

FIG. 22 is a schematic diagram of an electronic device according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. Throughout the specification, when a part is referred to as being “connected” to another part, this may include not only “directly connected” but also “indirectly connected” with another element interposed therebetween.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. At least one of X, Y, and Z” and “at least one selected X, Y and Z” can be interpreted as one X, one Y, one Z, or some combination of two or more of X, Y or Z (e.g., XYZ, XYY, YZ, ZZ). It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “below,” “above,” and the like, may be used for descriptive purposes to describe one element or feature's relationship to another element(s) or feature(s) as illustrated in the figures. Spatially relative terms are intended to encompass different orientations in use, operation, and/or manufacture in addition to the orientation depicted in the figures. For example, if the device shown in the figures is turned over, elements depicted as being “below” other elements or features may be positioned in a direction “above” the other elements or features. Thus, in an embodiment, the term “below” may encompass both an orientation of above and below. Further, the device may be oriented in other directions (e.g., rotated 90 degrees or in other directions), and thus the spatially relative terms used herein may be interpreted accordingly.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Various embodiments may be described with reference to the drawings, which illustrate idealized embodiments. Accordingly, it will be appreciated that the shapes may vary depending on, for example, tolerances and/or manufacturing techniques. Thus, embodiments disclosed herein are not to be construed as limited to the particular shapes shown, but rather as including changes in shapes that occur, for example, as a result of manufacturing. As such, the shapes shown in the figures may not depict actual shapes of regions of the apparatus, and embodiments of the disclosure are not limited thereto.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

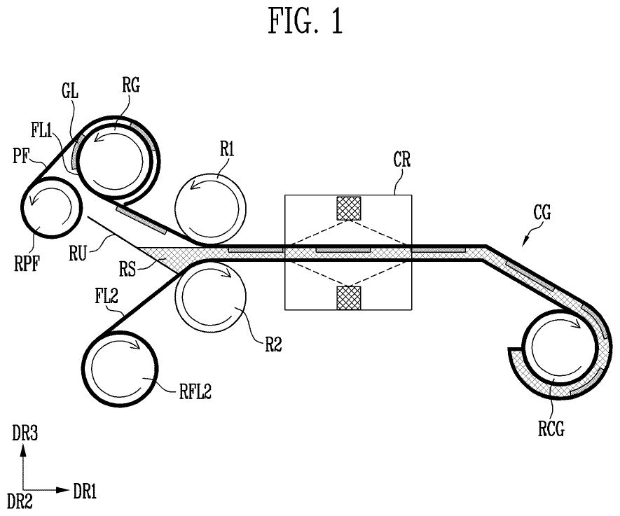

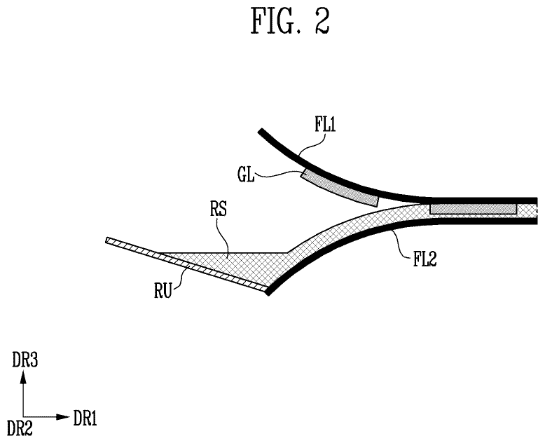

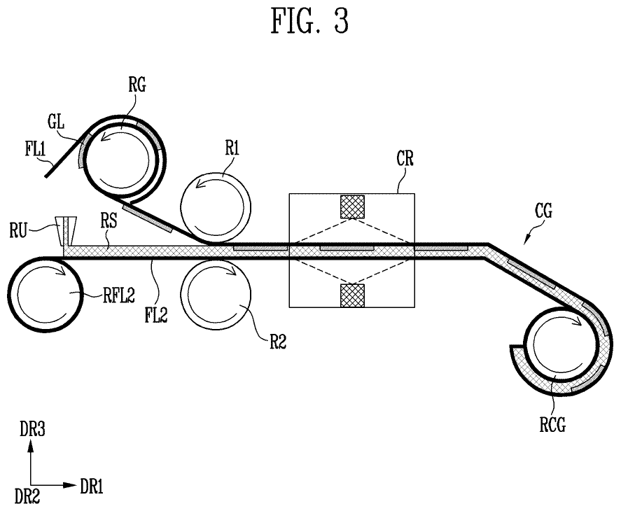

FIG. 1 is a schematic view of an apparatus for manufacturing coated glass according to an embodiment. FIG. 2 is an enlarged schematic view of an apparatus for manufacturing coated glass according to an embodiment. FIGS. 3 to 7 are schematic views of an apparatus for manufacturing coated glass according to an embodiment. FIGS. 8 to 13 are cross-sectional views of a coated glass according to an embodiment. The coated glass CG shown in FIGS. 8 to 13 maybe be manufactured by an apparatus for manufacturing coated glass according to an embodiment. In description of FIGS. 3 to 7, any repetitive detailed description of the same or like elements as those in FIG. 1 may be omitted.

Referring to FIGS. 1 to 13, in an embodiment, the coated glass CG to be manufactured by the apparatus for manufacturing coated glass may include at least one glass GL and a resin RS coated on the glass GL. In an embodiment, the coated glass CG may be applied to a display device and/or an electronic device including a display device. In an embodiment, for example, a part of the film of the coated glass CG may be removed and then attached to a display panel or the like of a display device.

Referring to FIG. 1, an embodiment of the apparatus for manufacturing coated glass may include a substrate supply unit RG, a resin supply unit RU, a first film removing unit RPF, coating unit R1, R2, a curing unit CR, and/or a glass winding unit RCG.

The substrate supply unit RG may serve to provide a substrate to the coating unit R1, R2. In an embodiment, for example, the substrate supply unit RG may include a substrate unwinding roller around which the substrate is wound. The substrate supply unit RG (e.g., the substrate unwinding roller) may be rotationally driven by a rotating drive unit (not shown), but is not necessarily limited thereto.

The substrate may include a first film FL1, glasses GL, and/or a protective film PF. A first film FL1 may be attached on a first side (or first surface) of the glasses GL and a protective film PF may be attached on a second side (or second surface) of the glass GL, which is opposite to the first side. In an embodiment, the adhesive force of the first film FL1 to the glasses GL may be higher than the adhesive force of the protective film PF to the glasses GL, but is not necessarily limited thereto. In such an embodiment where the adhesive force of the protective film PF is relatively low, the protective film PF can be easily removed from the substrate.

The first film removing unit RPF may serve to remove the protective film PF of the substrate. The first film removing unit RPF may include a protective film unwinding roller around which the protective film PF separated from the substrate is wound. The first film removing unit RPF (or the protective film unwinding roller) may be driven to rotate by a rotating drive unit (not shown), but is not necessarily limited thereto.

In an embodiment, as described above, the substrate wound on the substrate supply unit RG is unwound and the protective film PF may be removed. The removed protective film PF is wound around the first film removing unit RPF, and the glasses GL may be transferred to the coating unit R1, R2 side while being attached to the first film FL1.

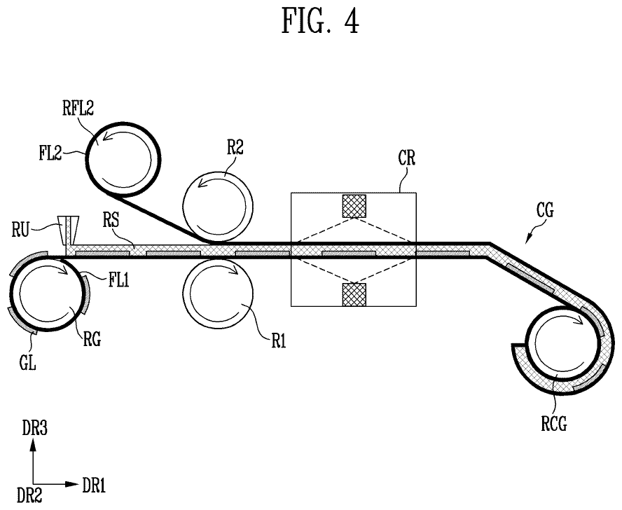

The resin supply unit RU may serve to store the resin RS and supply the resin RS onto the first film FL1 and/or the glasses GL. In an embodiment, for example, as shown in FIGS. 1 and 2, the resin supply unit RU may include or define a resin bath that receives the resin RS. According to an embodiment, as shown in FIGS. 3 and 4, the resin supply unit RU may coat the resin RS on the first film FL1, the glasses GL, and/or the second film FL2. In an embodiment, the resin supply unit RU may include, but is not necessarily limited to, a slit coater, a dispenser, a curtain coater, an inkjet device, or the like.

The resin supply unit RU may be disposed between the substrate supply unit RG and the coating unit R1, R2. The resin RS in the resin supply unit RU may be provided on the first film FL1 and/or the glasses GL in a process in which the glasses GL are attached to the first film FL1 and transferred to the coating unit R1, R2. In an embodiment, the material of the resin RS may have a viscosity of about 10,000 cps or less, but is not limited thereto.

The coating unit R1, R2 may include a first roller R1 and/or a second roller R2. The first roller R1 may convey the first film FL1 and/or the glasses GL. The second roller R2 may convey the second film FL2. The first film FL1 and the second film FL2 are brought into close contact with the resin RS between the first roller R1 and the second roller R2, so that the resin RS can be filled around the glasses GL. In an embodiment, for example, the first roller R1 and the second roller R2 may provide pressure for coating the resin RS around the glasses GL.

The first roller R1 and the second roller R2 may be spaced apart from each other. The first roller R1 and the second roller R2 may be spaced apart to allow the first film FL1, the glasses GL, and/or the second film FL2 to pass therebetween. The thickness of the coated glass CG can be controlled by adjusting the gap between the first roller R1 and the second roller R2. In an embodiment, for example, the gap between the first roller R1 and the second roller R2 may be equal to the thickness of the coated glass CG. In an embodiment, as shown in FIG. 3, the first roller R1 may be located above the second roller R2, but is not necessarily limited thereto. In another embodiment, for example, as shown in FIG. 4, the second roller R2 is located above the first roller R1, and the arrangement of the first roller R1 and the second roller R2 may be variously changed.

In an embodiment, the apparatus for manufacturing coated glass may further include a second film supply unit RFL2 for supplying the second film FL2. The second film supply unit RFL2 may include a second film unwinding roller around which the second film FL2 is wound. The second film supply unit RFL2 (or the second film unwinding roller) may be driven to rotate by a rotating drive unit (not shown), but is not necessarily limited thereto.

In an embodiment, as shown in FIG. 2, the second film FL2 may be conveyed past the resin supply unit RU. In an embodiment, for example, the second film FL2 may serve to pull up the resin RS in the resin supply unit RU and provide or transfer the resin RS onto the first film FL1 and the glasses GL. The first film FL1 and the second film FL2 are in close (indirect) contact with each other as the first film FL1 and the second film FL2 are closer to each other between the first roller R1 and the second roller R2, so that the pressure and the speed of the resin RS can be increased. At this time, undesired bubbles may move to the resin supply unit RU where the pressure is low, so that the bubbles around the glasses GL may be effectively removed and the resin RS may be uniformly filled around the glasses GL.

The curing unit CR may be disposed between the coating unit R1, R2 and the glass winding unit RCG. The first film FL1 and the second film FL2 that are in close contact with each other in the coating unit R1 and R2 may be transferred and provided to the curing unit CR. The resin RS filled around the glasses GL between the first film FL1 and the second film FL2 passes through the curing unit CR and may be cured.

The curing unit CR may include an ultraviolet (UV) irradiation unit. In an embodiment, for example, the curing unit CR may include a first UV irradiation unit and a second UV irradiation unit. The first UV irradiation unit may be disposed above the first film FL1. The second UV irradiation unit may be disposed below the second film FL2. However, the invention is not necessarily limited thereto, and the curing unit CR may be variously configured.

According to an embodiment, the curing unit CR may include a heating unit. In an embodiment, for example, the curing unit CR may include a first heating unit and a second heating unit. The first heating unit may be disposed above the first film FL1. The second heating unit may be disposed below the second film FL2. However, the invention is not necessarily limited thereto, and the curing unit CR may be variously configured.

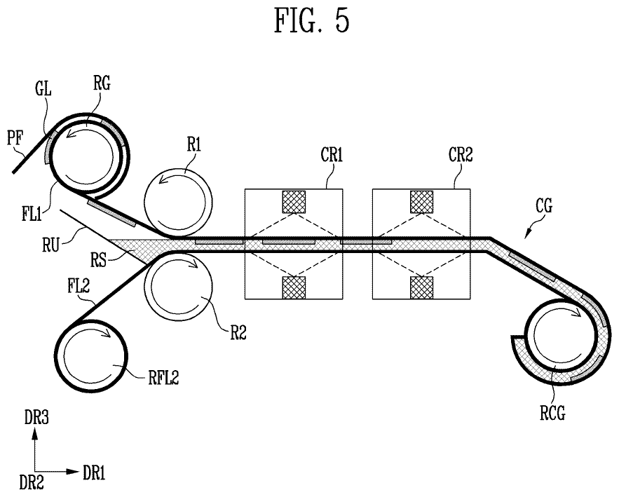

According to an embodiment, as shown in FIG. 5, the curing unit CR1, CR2 may include a first curing unit CR1 and a second curing unit CR2. In such an embodiment, the first curing unit CR1 may include an UV irradiation unit. In an embodiment, for example, the first curing unit CR1 may include a first UV irradiation unit and a second UV irradiation unit. The first UV irradiation unit may be disposed above the first film FL1. The second UV irradiation unit may be disposed below the second film FL2. However, the invention is not necessarily limited thereto, and the first curing unit CR1 may be variously configured.

In such an embodiment, the second curing unit CR2 may include a heating unit. In an embodiment, for example, the second curing unit CR2 may include a first heating unit and a second heating unit. The first heating unit may be disposed above the first film FL1. The second heating unit may be disposed below the second film FL2. However, the invention is not necessarily limited thereto, and the second curing unit CR2 may be variously configured.

In an embodiment, the first curing unit CR1 may be disposed between the coating unit R1, R2 and the second curing unit CR2, but is not necessarily limited thereto.

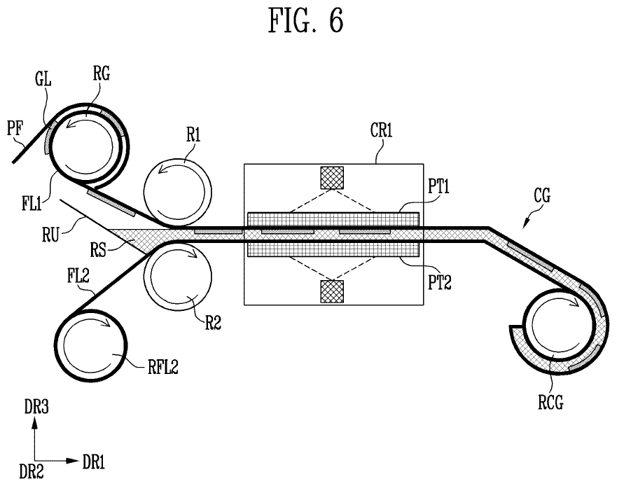

According to an embodiment, as shown in FIG. 6, the first curing unit CR1 may further include a first plate PT1 and/or a second plate PT2. The first plate PT1 and second plate PT2 may press the first film FL1 and/or the second film FL2 to improve the flatness of the coated glass CG. In an embodiment, for example, the first plate PT1 may be disposed above the first film FL1, and the second plate PT2 may be disposed below the second film FL2. The first plate PT1 may press the first film FL1, and the second plate PT2 may press the second film FL2. In an embodiment, the gap between the first plate PT1 and the second plate PT2 may be the same as the gap between the first roller R1 and the second roller R2. According to an embodiment, a gap between the first plate PT1 and the second plate PT2 may be less than a gap between a first roller R1 and a second roller R2. The gap between the plates PT1, PT2 can be adjusted to press the first film FL1 and/or the second film FL2, thereby improving the flatness of the coated glass CG and improving the surface quality. In an embodiment, the first plate PT1 and/or the second plate PT2 may include or be formed of glass material or quartz material, but is not necessarily limited thereto.

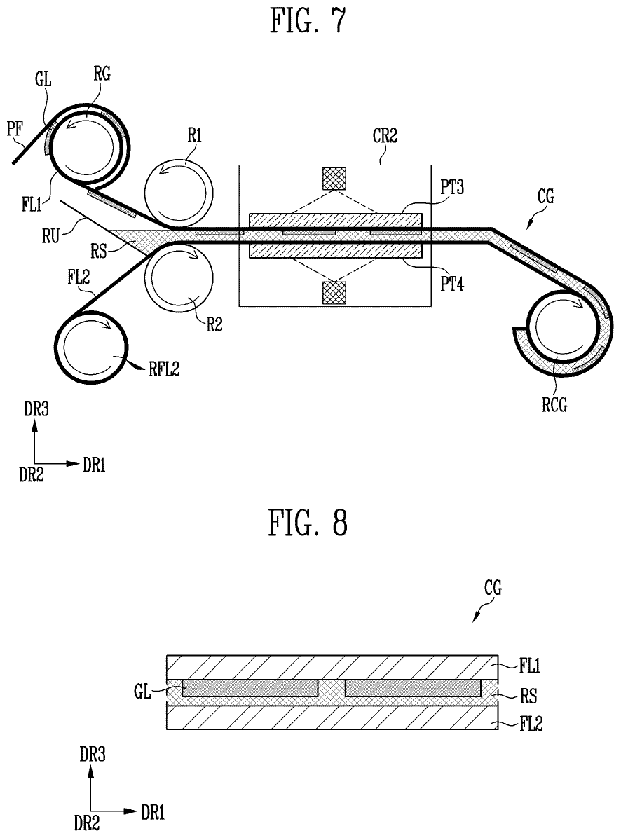

According to an embodiment, as shown in FIG. 7, the second curing unit CR2 may further include a third plate PT3 and/or a fourth plate PT4. The third plate PT3 and fourth plate PT4 may press the first film FL1 and/or the second film FL2 to improve the flatness of the coated glass CG. In an embodiment, the third plate PT3 and fourth plate PT4 may include a hot plate. In such an embodiment, the resin RS filled around the glasses GL between the first film FL1 and the second film FL2 may be thermally cured by the third plate PT3 and fourth plate PT4, but is not necessarily limited thereto.

In such an embodiment, the third plate PT3 may be disposed above the first film FL1, and the fourth plate PT4 may be disposed below the second film FL2. The third plate PT3 may pressurize and/or heat-treat the first film FL1, and the fourth plate PT4 may pressurize and/or heat-treat the second film FL2. In an embodiment, the gap between the third plate PT3 and the fourth plate PT4 may be the same as the gap between the first roller R1 and the second roller R2. According to an embodiment, a gap between the third plate PT3 and the fourth plate PT4 may be less than a gap between a first roller R1 and a second roller R2. The gap between the plates PT3, PT4 can be adjusted to press the first film FL1 and/or the second film FL2, thereby improving the flatness of the coated glass CG and improving the surface quality.

Although FIG. 6 illustrates an embodiment in which the apparatus for manufacturing coated glass includes the first curing unit CR1, and FIG. 7 illustrates an embodiment in that the apparatus for manufacturing coated glass includes the second curing unit CR2, the invention is not necessarily limited thereto, and as shown in FIG. 5, the apparatus for manufacturing coated glass may include the first curing unit CR1 and the second curing unit CR2 including the plates PT1 to PT4.

The glass winding unit RCG may serve to wind the coated glass CG that has been subjected to the coating and curing process. The glass winding unit RCG may include a glass winding roller around which the coated glass CG is wound. The glass winding unit RCG (or the glass winding roller) may be rotationally driven by a rotating drive unit, but is not necessarily limited thereto. The coated glass CG may be provided in a state of being wound on a glass winding roller, or may be subjected to a subsequent process such as cutting, peeling or adhering the film. A detailed description thereof will hereinafter be given with reference to FIGS. 14 to 18.

Referring to FIG. 8, the coated glass CG manufactured by the above-described apparatus for manufacturing coated glass may include the glasses GL between the first film FL1 and the second film FL2 and the resin RS filled around the glasses GL. The glasses GL may be spaced apart from each other in a first direction DR1. An upper surface of the glasses GL is attached on the first film FL1, and a lower surface and a side surface of the glasses GL may be covered by the resin RS.

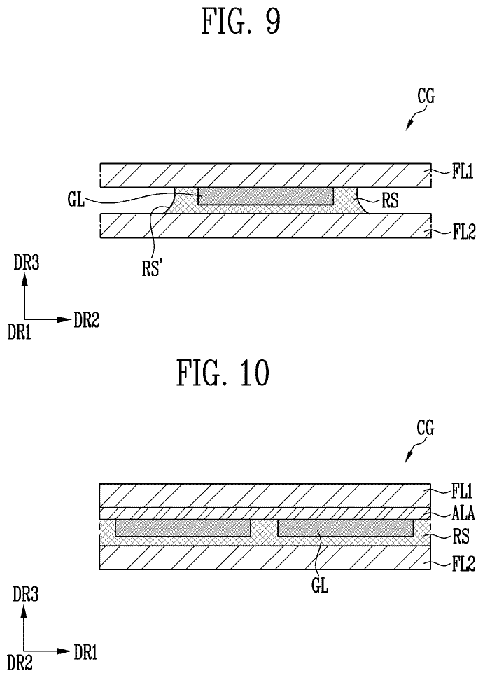

Referring to FIG. 9, the side surface of the resin RS may include a recess RS′. The recess RS′ may have a shape recessed inwardly or toward the glass GL. The recess RS′ may be formed by a contact angle between the resin RS and the films FL1, FL2 and gravity. The recess RS′ may be located inside the side or edge of the first film FL1. The recess RS′ may be located inside the side or edge of the second film FL2. The recess RS′ can be cut off and removed in a subsequent process.

Referring to FIG. 10, the coated glass CG may further include a first adhesive layer ALA. The first adhesive layer ALA may be disposed between the first film FL1 and the glasses GL. The first adhesive layer ALA may be provided on the first film FL1 to attach the glasses GL in the process of preparing and supplying the substrate described above.

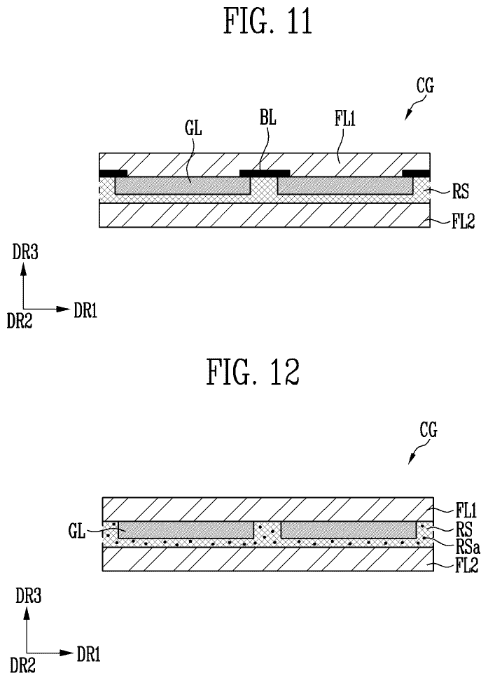

Referring to FIG. 11, the coated glass CG may further include a light shielding layer BL. The light shielding layer BL may be disposed between the first film FL1 and the glasses GL. The light shielding layer BL may overlap an edge of the glasses GL in a third direction DR3 or a thickness direction of the glasses GL. In an embodiment, the light shielding layer BL may be printed on the first film FL1, but is not necessarily limited thereto.

Referring to FIG. 12, in an embodiment, the resin RS may include a UV absorber RSa. In such an embodiment, it is possible to easily cut the coated glass CG by distinguishing the lines or edges of the glasses GL using UV rays and UV cameras. In an embodiment, for example, where the resin RS includes a UV absorber, the area around the glasses GL may appear darker than the glasses GL, thereby distinguishing the edges of the glasses GL in a process of cutting the coated glass CG.

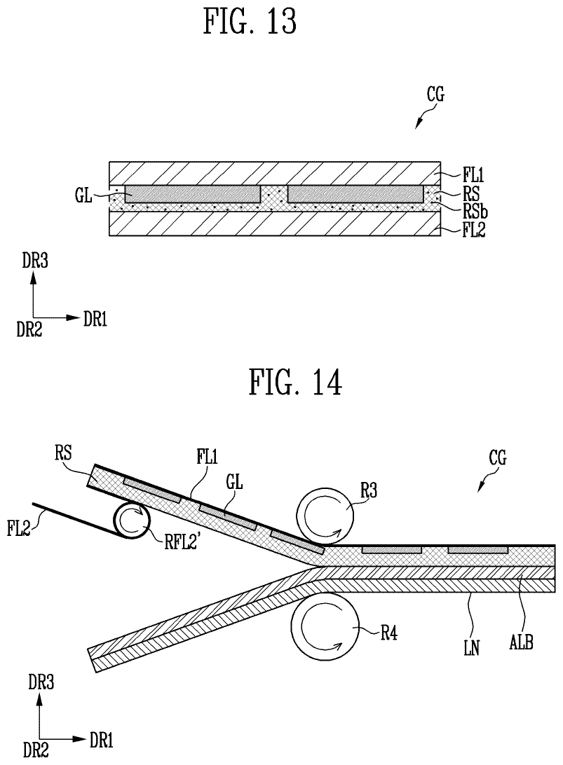

Referring to FIG. 13, in an embodiment, the resin RS may include a fluorescent additive RSb. In such an embodiment, it is possible to easily cut the coated glass CG by distinguishing the lines or edges of the glasses GL. In an embodiment, for example, when the resin RS includes a fluorescent additive, the area around the glasses GL may appear brighter than the glasses GL, thereby distinguishing the edges of the glasses GL and cutting the coated glass CG.

In an embodiment, the coated glass CG includes the glasses GL and may be wound around a glass winding unit RCG (or a glass winding roller) to be completed in a roll form. In another embodiment, the coated glass CG in roll form can be attached with a release film in a subsequent process, or the glasses GL can be separated from one another via a cutting process. A detailed description thereof will hereinafter be given with reference to FIGS. 14 to 18.

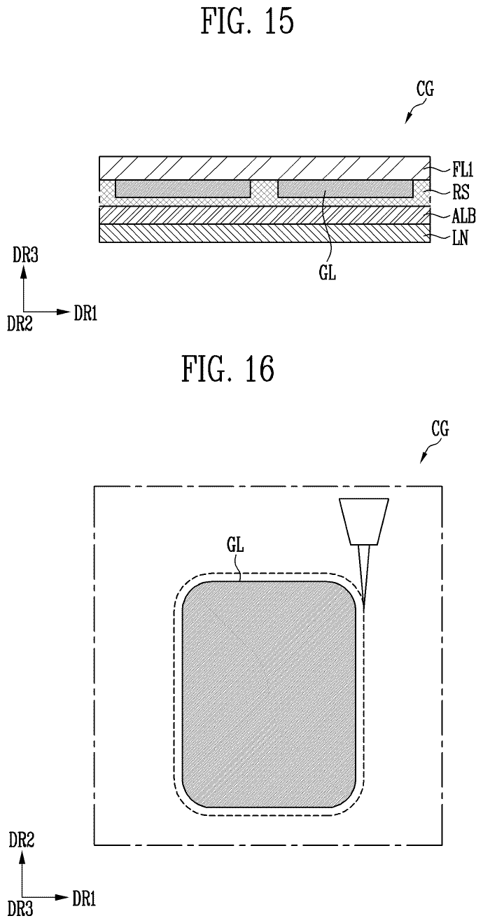

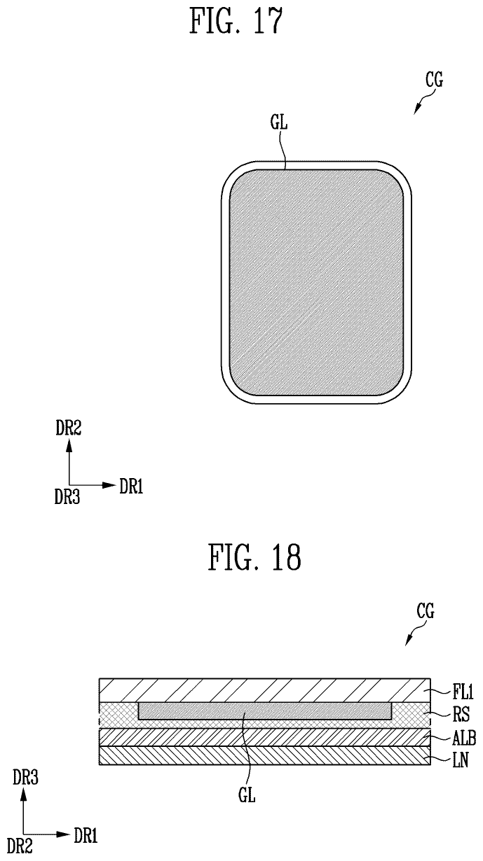

FIG. 14 is a schematic view of an apparatus for manufacturing coated glass according to an embodiment. FIG. 15 is a cross-sectional view of a coated glass according to an embodiment. FIG. 16 is a schematic view of an apparatus for manufacturing coated glass according to an embodiment. FIG. 17 is a top view of a coated glass according to an embodiment. FIG. 18 is a cross-sectional view of a coated glass according to an embodiment. The coated glass CG shown in FIGS. 17 and 18 can be manufactured by an apparatus for manufacturing coated glass according to an embodiment.

Referring to FIG. 14, the apparatus for manufacturing coated glass may further include a second film removing unit RFL2′ and/or attachment unit R3, R4.

The second film removing unit RFL2′ may serve to remove the second film FL2 of the coated glass CG. The second film FL2 of coated glass CG may be removed to expose the resin RS. The second film removing unit RFL2′ may include a second film winding roller around which the second film FL2 separated from the coated glass CG is wound. The second film removing unit RFL2′ (or the second film winding roller) may be rotationally driven by a rotating drive unit (not shown), but is not necessarily limited thereto. The coated glass CG from which the second film FL2 has been removed can be conveyed to the side of the attachment unit R3, R4.

In an embodiment, the apparatus for manufacturing coated glass may further include a release film supply unit (not shown). The release film supply unit may serve to provide a release film LN on the resin RS. The release film supply unit may include a release film unwinding roller around which the release film LN is wound. The release film supply unit (or the release film unwinding roller) may be rotationally driven by a rotating drive unit (not shown), but is not necessarily limited thereto.

In an embodiment, a second adhesive layer ALB may be further disposed on the upper surface of the release film LN. The release film LN can be attached onto the resin RS by the second adhesive layer ALB. However, the present disclosure is not necessarily limited thereto, and the second adhesive layer ALB may be omitted according to an embodiment.

The attachment unit R3, R4 may include a third roller R3 and/or a fourth roller R4. The third roller R3 may convey the first film FL1, the glasses GL, and/or the resin RS. The fourth roller R4 may convey the release film LN and/or the second adhesive layer ALB. The first film FL1 and the release film LN are brought into close (indirect) contact with each other between the third roller R3 and the fourth roller R4, so that the resin RS and the release film LN can be attached to each other. In an embodiment, for example, the third roller R3 and the fourth roller R4 can provide pressure for the resin RS and the release film LN to be attached.

The third roller R3 and the fourth roller R4 may be spaced apart from each other. The third roller R3 and the fourth roller R4 may be spaced apart to allow the first film FL1, the glasses GL, the resin RS, the second adhesive layer ALB, and/or the release film LN to pass therebetween. The third roller R3 may be located above the fourth roller R4, but is not necessarily limited thereto.

Referring to FIG. 15, the coated glass CG manufactured by the apparatus for manufacturing coated glass may include the glasses GL between the first film FL1 and the second film FL2 and the resin RS filled around the glasses GL. The glasses GL may be spaced apart from each other in the first direction DR1. An upper surface of the glasses GL is attached on the first film FL1, and a lower surface and a side surface of the glasses GL may be covered by the resin RS. The upper surface of the second adhesive layer ALB may be in (direct) contact with the resin RS. The lower surface of the second adhesive layer ALB can be in (direct) contact with the release film LN.

Referring to FIGS. 16 to 18, the apparatus for manufacturing coated glass may further include a cutting unit. In an embodiment, for example, the coated glass CG may be cut along the periphery of a line or edge of the glass GL to separate the glasses GL from one another. In an embodiment, for example, the first film FL1, the resin RS, the second adhesive layer ALB, and/or the release film LN may be cut along the periphery of a line or edge of the glass GL to separate the glass GL from each other. In an embodiment, even if the coated glass GL is cut, the sides of the glass GL may be covered by the resin RS. In an embodiment, the cutting unit may include, but is not necessarily limited to, a laser cutting device or a punching device.

According to embodiments of the disclosure, as described above, by coating the resin RS on the glass GL using the roll-to-roll gap coating, it is possible to easily control the thickness and shape of the resin RS, thereby improving the flatness of the resin SR, and reducing the manufacturing cost.

Hereinafter, a display device including the coated glass CG manufactured by the above-described apparatus for manufacturing coated glass and an electronic device including the display device will be described.

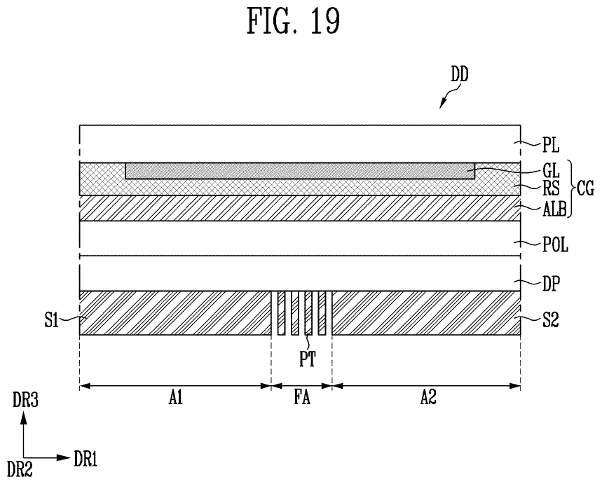

FIG. 19 is a cross-sectional view of a display device according to an embodiment.

Referring to FIG. 19, an embodiment of the display device DD may include a first area A1, a second area A2, and/or a folding area FA. The folding area FA may be located between the first area A1 and the second area A2. The first area A1, the folding area FA, and the second area A2 may be sequentially arranged along the first direction DR1. The folding area FA may be folded or unfolded (i.e., foldable) about a folding axis (or folding line) extending in a second direction DR2 intersecting the first direction DR1.

The display device DD may include a display panel DP, support plates S1, S2, PT, a polarizing member POL, a coated glass CG, and/or a protective layer PL.

The display panel DP can be folded or unfolded around a folding axis. The display panel DP can include a first area A1, a second area A2, and a folding area FA. The folding area FA may be located between the first area A1 and the second area A2. The first area A1, the folding area FA, and the second area A2 may be sequentially arranged along the first direction DR1. The folding area FA may be folded or unfolded about a folding axis (or folding line) extending in a second direction DR2 intersecting the first direction DR1.

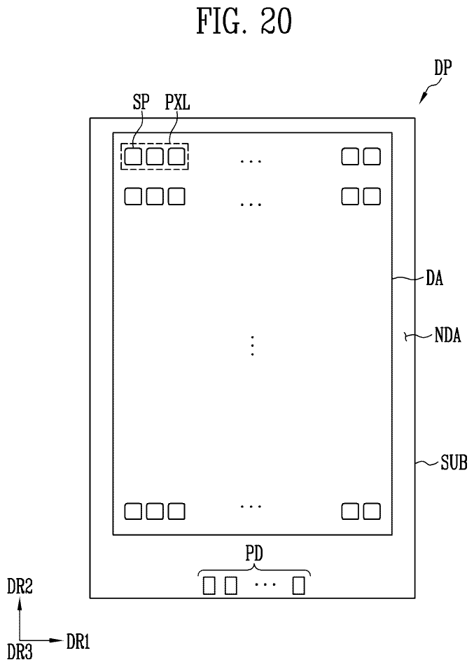

FIG. 20 is a plan view of the display panel according to the embodiment of FIG. 19.

Referring to FIG. 20, an embodiment of the display panel DP may include a display area DA and a non-display area NDA. The display panel DP can display an image through the display area DA. The non-display area NDA may be disposed in the periphery of the display area DA.

The display panel DP may include a substrate SUB, sub-pixels SP, and pads PD.

The sub-pixels SP may be disposed in the display area DA on the substrate SUB. The sub-pixels SP may be arranged in a matrix form along a first direction DR1 and a second direction DR2 intersecting the first direction DR1. However, embodiments are not so limited. In an embodiment, for example, the sub-pixels SP may be arranged in a zigzag pattern along the first direction DR1 and the second direction DR2. In an embodiment, for example, the sub-pixels SP may be arranged in a pentile form. The first direction DR1 may be a row direction, and the second direction DR2 may be a column direction. Two or more sub-pixels of the sub-pixels SP may constitute one pixel PXL.

The pads PD may be disposed in the non-display area NDA on the substrate SUB. The pads PD may be electrically connected to the sub-pixels SP through wirings.

The pads PD can interface the display panel DP to other components of the display device DD. In an embodiment, voltages and signals necessary for operation of components included in the display panel DP can be provided from the driver integrated circuit through the pads PD.

In an embodiment, a circuit board may be electrically connected to the pads PD by using a conductive adhesive member such as an anisotropic conductive film. In such an embodiment, the circuit board may be a flexible circuit board or a flexible film having a flexible material. The driver integrated circuit may be mounted to a circuit board and electrically connected to the pads PD.

In an embodiment, the display area DA may have various shapes. The display area DA may have a shape of a closed loop including straight and/or curved sides. In an embodiment, for example, the display area DA can have shapes of a polygon, a circle, a semicircle, an ellipse, or the like.

In an embodiment, the display panel DP may have a flat display surface. In another embodiment, the display panel DP may have an at least partially round display surface. In an embodiment, the display panel DP may be bendable, foldable, or rollable. In such an embodiment, the display panel DP and/or the substrate SUB may include materials having a flexible property.

The display panel DP may include a substrate, display elements coupled on the substrate, at least one conductive line coupled with the substrate and electrically connected with the display elements, and/or a thin film encapsulation layer.

Display elements are disposed on the substrate and can form or define a large number of pixels. In an embodiment, for example, the display elements can be arranged in a matrix on the substrate to form pixels of the display panel DP. In an embodiment, for example, the display elements may include, but are not necessarily limited to, an organic light emitting diode (OLED).

The conductive line may include at least one gate signal line or at least one data signal line. In an embodiment, the conductive line may include gate signal lines and data signal lines. In such an embodiment, the gate signal lines and the data signal lines are arranged in a matrix form, and the display elements are arranged in alignment adjacent to a point where the lines intersect, so that the display elements can be electrically connected to the lines.

The thin film encapsulation layer can cover the substrate, the display elements, and/or the conductive line to prevent oxygen and moisture from entering from the outside. In an embodiment, the thin film encapsulation layer may be formed by alternately laminating one or more organic layers and one or more inorganic layers. In such an embodiment, the outermost layer of the thin film encapsulation layer may be formed of an inorganic layer to effectively prevent moisture penetration, but is not limited thereto.

Referring back to FIG. 19, the support plates S1, S2, and PT may be disposed below the display panel DP. The support plates S1, S2, and PT can be placed on the bottom surface of the display panel DP to support the display panel DP and serve to reinforce rigidity. The support plates S1, S2, and PT may include or be formed of, but are not necessarily limited to, carbon fiber reinforced plastic, glass fiber reinforced plastic, and/or stainless steel or the like.

The support plates S1, S2, and PT may include a first support portion S1, a second support portion S2, and/or a pattern portion PT. The pattern portion PT may be located between the first support portion S1 and the second support portion S2. The first support portion S1, the pattern portion PT, and the second support portion S2 may be sequentially arranged along the first direction DR1. The pattern portion PT may be folded or unfolded about a folding axis (or folding line) extending in a second direction DR2 intersecting the first direction DR1.

The first support portion S1 may overlap the first area A1 in a third direction DR or a thickness direction of the display panel DP. In an embodiment, for example, the first support portion S1 may overlap the first area A1 in the third direction DR3 in the unfolded state. The second support portion S2 may overlap with the second area A2. In an embodiment, for example, the second support portion S2 may overlap the second area A2 in the third direction DR3 in the unfolded state.

The pattern portion PT may overlap the folding area FA. The pattern portion PT can serve to minimize deformation of the display panel DP in the folding area FA.

The pattern portion PT may define opening patterns. The opening patterns of the pattern portion PT may have a through hole shape, but are not necessarily limited thereto.

The polarizing member POL can be placed on top of the display panel DP. An adhesive layer may be further disposed between the polarizing member POL and the display panel DP. The polarizing member POL can serve to prevent deterioration of visibility due to reflection of external light. In another embodiment, the polarizing member POL may be omitted.

The coated glass CG may be placed on top of the display panel DP. The coated glass CG may be attached to the upper surface of the polarizing member POL. A lower surface of the second adhesive layer ALB of the coated glass CG may be in contact with the polarizing member POL, and an upper surface of the glass GL and/or an upper surface of a resin RS may be in contact to the protective layer PL. According to an embodiment, when second adhesive layer ALB is omitted, the resin RS of the coated glass CG may be in contact with the polarizing member.

Although FIG. 19 illustrates an embodiment in which the first film FL1 and the release film LN are removed from the coated glass CG of FIG. 18 and attached to the upper surface of the polarizing member POL, the invention is not necessarily limited thereto. In an embodiment, for example, referring to FIGS. 8 and 19, after the coated glass CG is cut, the first film FL1 and the second film FL2 may be removed and the coated glass CG may be attached to the upper surface of the polarizing member POL. The process of cutting the coated glass CG has been described with reference to FIG. 16, and thus any repetitive detailed description thereof will be omitted. The lower surface of the resin RS of the coated glass CG may be in contact with the polarizing member POL, and the upper surface of the glass GL and/or the upper surface of a resin RS may be in contact to the protective layer PL.

Referring to FIGS. 10 and 19, after the coated glass CG is cut, the first film FL1 and the second film FL2 may be removed and the coated glass CG may be attached to the upper surface of the polarizing member POL. The process of cutting the coated glass CG has been described with reference to FIG. 16, and thus any repetitive detailed description thereof will be omitted. A first adhesive layer ALA may further be disposed between the glass GL and/or the resin RS and the protective layer PL. The lower surface of the resin RS of the coated glass CG is in contact with the polarizing member POL, and the upper surface of the first adhesive layer ALA is in contact with a protective layer PL.

Referring to FIGS. 11 and 19, after the coated glass CG is cut, the first film FL1 and the second film FL2 may be removed and the coated glass CG may be attached to the upper surface of the polarizing member POL. The process of cutting the coated glass CG has been described with reference to FIG. 16, and thus any repetitive detailed description thereof will be omitted. A light shielding layer BL may further be arranged between the glass GL and/or the resin RS and the protective layer PL. The lower surface of the resin RS of the coated glass CG may be in contact with the polarizing member POL, and the upper surface of the glass GL and/or the upper surface of a light shielding layer BL may also be in contact with a protective layer PL.

Referring to FIGS. 12, 13, and 19, after the coated glass CG is cut, the first film FL1 and the second film FL2 may be removed and the coated glass CG may be attached to the upper surface of the polarizing member POL. In an embodiment where the resin RS contains the UV absorber RSa as shown in FIG. 12, the coated glass CG can be easily cut by distinguishing the lines or edges of the glasses GL as described above. As described above, in an embodiment where the resin RS contains the fluorescent additive RSb as shown in FIG. 13, the coated glass CG can be easily cut by distinguishing the lines or edges of the glasses GL. The process of cutting the coated glass CG has been described with reference to FIG. 16, and thus any repetitive detailed description thereof will be omitted.

The display device DD according to an embodiment can be applied to a variety of electronic devices. The electronic device according to an embodiment includes the display device DD described above, and may further include a module or a device having another additional function in addition to the display device DD.

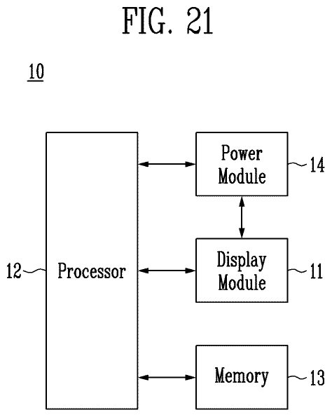

FIG. 21 is a block diagram of an electronic device according to an embodiment.

Referring to FIG. 21, an electronic device 10 according to an embodiment may include a display module 11, a processor 12, a memory 13, and a power supply module 14.

The processor 12 may include at least one selected from a central processing unit (CPU), an application processor (AP), a graphics processing unit (GPU), a communication processor (CP), an image signal processor (ISP), or a controller.

Data information used for operation of the processor 12 or the display module 11 may be stored in the memory 13. When the processor 12 executes an application stored in the memory 13, an image data signal and/or an input control signal are transmitted to the display module 11, and the display module 11 may process the received signal and output image information through a display screen, that is, a pixel.

The power supply module 14 may include a power supply module such as a power adapter or a battery device, and a power conversion module that converts power supplied by the power supply module to generate power required for operation of the electronic device 10.

At least one of the above-described components of the electronic device 10 may be included in the display device according to the above-described embodiments. In addition, some of the individual modules that are functionally included in one module may be included in the display device and the other may be provided separately from the display device. In an embodiment, for example, the display device includes the display module 11, and the processor 12, the memory 13, and the power supply module 14 may be provided in a form of another device in the electronic device 10 other than the display device.

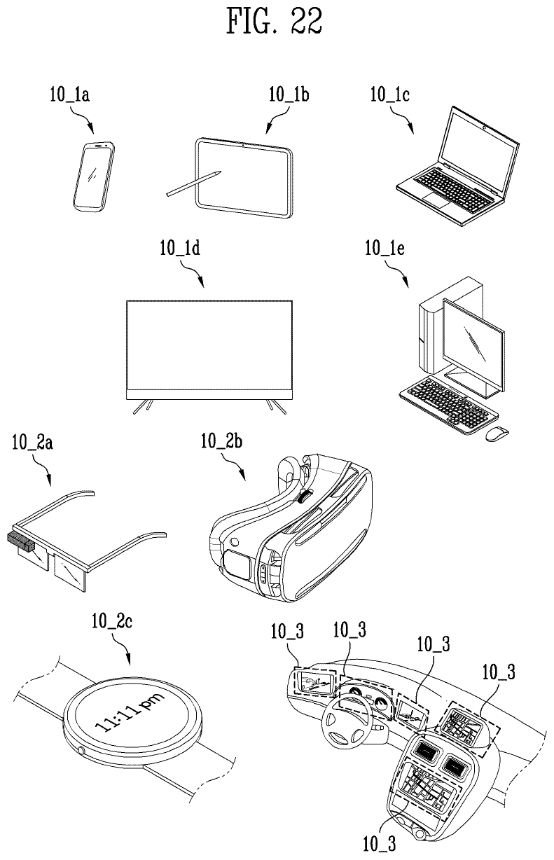

FIG. 22 is schematic diagrams of an electronic device according to various embodiments.

Referring to FIG. 22, various electronic devices to which the display device according to embodiments is applied may include an electronic device for image display such as a smartphone 10_1a, a tablet personal computer (PC) 10_1b, a laptop 10_1c, a TV 10_1d, and a desk monitor 10_1e, as well as a wearable electronic device including a display module such as smart glasses 10_2a, a head-mounted display 10_2b, and a smart watch 10_2c, a vehicle electronic device 10_3 including a display module, such as a center information display (CID) disposed on an instrument panel, a center fascia, and a dashboard of an automobile, a room mirror display, and the like.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An apparatus for manufacturing coated glass comprising:
a substrate supply unit on which a substrate is wound, wherein the substrate includes glasses, a first film attached to a first side of the glasses and a protective film attached to a second side of the glasses;
a first film removing unit which removes the protective film from the substrate;
a resin supply unit which supplies a resin on the first film and the glasses of the substrate;
a first roller which conveys the first film; and
a second roller spaced apart from the first roller and which conveys a second film,
wherein the first film and the second film are in close contact between the first roller and the second roller, and the resin is filled around the glasses between the first film and the second film.

2. The apparatus for manufacturing coated glass of claim 1,
wherein the second film pulls up the resin from the resin supply unit and provides the resin on the first film and the glasses.

3. The apparatus for manufacturing coated glass of claim 1,
wherein the resin supply unit coats the resin on the second film.

4. The apparatus for manufacturing coated glass of claim 1,
wherein the resin supply unit coats the resin on the first film and the glasses.

5. The apparatus for manufacturing coated glass of claim 1,
wherein a thickness of the coated glass is equal to a gap between the first roller and the second roller.

6. The apparatus for manufacturing coated glass of claim 1, further comprising:
a curing unit which cures the resin filled around the glasses between the first film and the second film.

7. The apparatus for manufacturing coated glass of claim 6,
wherein the curing unit includes a first plate which presses the first film and a second plate which presses the second film.

8. The apparatus for manufacturing coated glass of claim 1, further comprising:
a winding roller on which the coated glass is wound.

9. The apparatus for manufacturing coated glass of claim 1, further comprising:
a second film removing unit which removes the second film.

10. The apparatus for manufacturing coated glass of claim 9, further comprising:
an attachment unit which attaches a release film on the resin.

11. The apparatus for manufacturing coated glass of claim 10,
wherein the attachment unit includes a third roller and a fourth roller, which are spaced apart from each other.

12. An electronic device comprising:
a display panel; and
a coated glass on the display panel,
wherein the coated glass is manufactured by the apparatus for manufacturing coated glass of claim 1.

13. The electronic device of claim 12,
wherein the coated glass includes glass on the display panel and a resin between the display panel and the glass.

14. The electronic device of claim 13,
the coated glass further comprises a first adhesive layer between the display panel and the resin.

15. The electronic device of claim 13, further comprising:
a protective layer on the coated glass.

16. The electronic device of claim 15,
wherein the coated glass further comprises a second adhesive layer between the glass and the protective layer.

17. The electronic device of claim 15,
wherein the coated glass further comprises a light shielding layer between the glass and the protective layer.

18. The electronic device of claim 17,
wherein the light shielding layer overlaps an edge of the glass.

19. The electronic device of claim 13,
wherein the resin comprises a UV absorber.

20. The electronic device of claim 13,
wherein the resin comprises a fluorescent additive.
